(19) United States
(12) Patent Application Publication
(10) Pub. No.: US 2026/0206148 A1
(43) Pub. Date: Jul. 16, 2026

(54) MULTIFUNCTIONAL POWER SUPPLY

(71) Applicant: Shenzhen Fuchengxiang Photoelectric Technology Co., Ltd., Shenzhen (CN)

(72) Inventor: Fuwen Meng, Ji'an (CN)

(21) Appl. No.: 19/057,078

(22) Filed: Feb. 19, 2025

(30) Foreign Application Priority Data
Jan. 16, 2025 (CN) 2025200997945

(51) Int. Cl. H05K 5/00; H02M 7/00

(52) U.S. Cl. CPC H05K 5/0017; H02M 7/003

(57) ABSTRACT

The present disclosure relates to a multifunctional power supply, including: a housing, where a transformer and a circuit board are disposed inside the housing, and the transformer is electrically connected to the circuit board; an output end that is connected to the housing and is exposed outside the housing, where the output end is electrically connected to the circuit board; and a function panel that is disposed on the housing in a replaceable manner, and is electrically connected to the circuit board. The multifunctional power supply provided in the present disclosure has the function panel that is disposed on the housing in the replaceable manner. The function panel can be directly switched to quickly achieve maintenance and system upgrade of the multifunctional power supply. Therefore, a control mode of an electrical appliance is adjusted and upgraded more conveniently and quickly, expanding application scenarios of the multifunctional power supply.

### TECHNICAL FIELD

The present disclosure relates to the field of outdoor power supply technologies, and in particular, relates to a multifunctional power supply.

### BACKGROUND

Landscape lamps are common outdoors. For example, decorative lights on trees along roads or underground lights on flower beds and grasslands in parks are a unique scenery on urban roads or in residential areas at night. In order to ensure use safety, these lamps usually use low-voltage direct-current power supplies or AC power supplies. Therefore, in order to ensure normal use of these landscape lamps, corresponding outdoor power supplies or outdoor transformers are disposed.

Certainly, power supplies are not just needed to be provided for the landscape lamps. With development of technologies, people require the landscape lamps to have more functions including light color changing, lighting manner changing, and the like that are difficult to be achieved via an existing outdoor transformer. Therefore, the landscape lamps usually need to be dismounted from a set of system for modifying, upgrading, or maintaining that is often troublesome and may affect use of landscape lamps in an entire area.

### SUMMARY

Embodiments of the present disclosure provide a multifunctional power supply, to improve maintenance and update convenience of an outdoor power supply device.

A multifunctional power supply provided in the present disclosure includes: a housing, where a transformer and a circuit board are disposed inside the housing, and the transformer is electrically connected to the circuit board; an output end that is connected to the housing and is exposed outside the housing, where the output end is electrically connected to the circuit board; and a function panel that is disposed on the housing in a replaceable manner, and is electrically connected to the circuit board.

In an embodiment, the circuit board includes an alternating current/direct current (AC/DC) conversion module, and the output end includes at least one of a DC output end and an AC output end.

In an embodiment, the DC output end and the AC output end are disposed on a same side of the housing and are disposed in regions.

In an embodiment, the housing is further provided with a selector switch, and the selector switch is electrically connected to the circuit board, to switch output of the output end, and implement full DC output or full AC output.

In an embodiment, the housing is provided with a wire clamping part on a side on which the output end is located, the wire clamping part includes an elastic clamp and an adjusting bolt, and the adjusting bolt is disposed at an opening of the elastic clamp to adjust a size of the opening of the elastic clamp.

In an embodiment, the function panel includes a control panel and a connecting frame, the control panel is disposed in the connecting frame, and the connecting frame is detachably connected to the housing.

In an embodiment, a plurality of elastic fasteners are uniformly distributed on the connecting frame, and a mounting groove is provided in the housing; and the connecting frame penetrates the mounting groove, and the elastic fastener is clamped to an edge of the mounting groove.

In an embodiment, the housing includes a first surface and a second surface that are disposed opposite to each other, and a peripheral surface connected between the first surface and the second surface; the peripheral surface includes a first peripheral surface and a second peripheral surface that are disposed opposite to each other, and a third peripheral surface and a fourth peripheral surface that are connected between the first peripheral surface and the second peripheral surface, and are disposed opposite to each other; and the connecting frame is detachably disposed on a side on which the first surface is located, and the output end is disposed on a side on which the fourth peripheral surface is located.

In an embodiment, the function panel further includes a data connecting terminal, and the data connecting terminal is detachably connected to a side on which the first peripheral surface is located.

In an embodiment, a connecting plate is disposed on an edge that is on the second surface and that is close to the third peripheral surface, and at least one connecting through hole is provided on the connecting plate.

The multifunctional power supply provided in the present disclosure has the function panel that is disposed on the housing in the replaceable manner. The function panel can be directly switched to quickly achieve maintenance and system upgrade of the multifunctional power supply. For example, a common function panel is replaced as a control panel with an intelligent control module, and output control of the multifunctional power supply is achieved by using mobile phone application (APP), and the like. Therefore, a control mode of an electrical appliance is adjusted and upgraded more conveniently and quickly, and a usage scenario of the multifunctional power supply is expanded.

### BRIEF DESCRIPTION OF THE DRAWINGS

To describe the technical solutions in the embodiments of the present disclosure or in the prior art more clearly, the following briefly introduces the accompanying drawings required for describing the embodiments or the prior art. Apparently, the accompanying drawings in the following description show merely some embodiments of the present disclosure, and a person of ordinary skill in the art may still derive other drawings from these accompanying drawings without creative efforts.

FIG. 1 is a schematic diagram of a structure of a multifunctional power supply according to an embodiment from a first perspective;

FIG. 2 is a first exploded view of a multifunctional power supply according to an embodiment;

FIG. 3 is a first exploded view of a multifunctional power supply according to an embodiment;

FIG. 4 is a first exploded view of a multifunctional power supply according to an embodiment; and

FIG. 5 is a first exploded view of a multifunctional power supply according to an embodiment.

Reference numerals:

100: housing; 200: function panel;

110: transformer; 120: circuit board; 130: output end; 140: selector switch; 150: wire clamping part; 160: connecting plate;

101: first surface; 102: second surface; 103: first peripheral surface; 104: second peripheral surface; 105: third peripheral surface; 106: fourth peripheral surface; 107: mounting groove;

131: DC output end; 132: AC output end; 151: elastic clamp; 152: adjusting bolt; 161: connecting through hole;

210: control panel; 220: connecting frame; 230: data connecting terminal; and 221: elastic fastener.

### DETAILED DESCRIPTION OF THE EMBODIMENTS

The following detailed description of preferred embodiments is a preferred mode for implementing the present disclosure. This description has no restrictive meaning. It is proposed to illustrate the general principle of the present disclosure.

It should be understood that in order to facilitate the understanding of the present disclosure, the terms "mounting", "connection", "coupling", and "installation" in the following description refer to a connection relationship in the accompanying drawings. For example, the "connection" may be a permanent connection or a detachable connection. In addition, the "connection" may be a direct connection or an indirect connection or a connection through another auxiliary part. Therefore, the above terms should not be limitations on actual connections of various components of the present disclosure.

It should be understood that the terms "length", "width", "top", "bottom", "front", "back", "left", "right", "vertical", "horizontal", "upper", "lower", "external" and "internal" refer to orientation or positioning relationships in the accompanying drawings for the purpose of understanding the present disclosure, and do not limit the actual position or orientation of the present disclosure. Therefore, the above terms should not be limitations on actual positions of various components of the present disclosure.

It should be understood that the terms "first", "second", and "one" in the following description refer to "at least one" or "one or more" in the embodiments. Specifically, the term "one" may refer to "one" in an embodiment, and may refer to "more than one" in another embodiment. Therefore, the above terms should not be limitations on actual numbers of components of the present disclosure.

To facilitate the understanding of the present disclosure, the present disclosure will be described completely below with reference to the related accompanying drawings. Preferred embodiments of the present disclosure are shown in the drawings. However, the present disclosure may be embodied in various forms without being limited to the embodiments described herein. On the contrary, these examples are provided such that the disclosure of the present disclosure can be understood thoroughly and comprehensively.

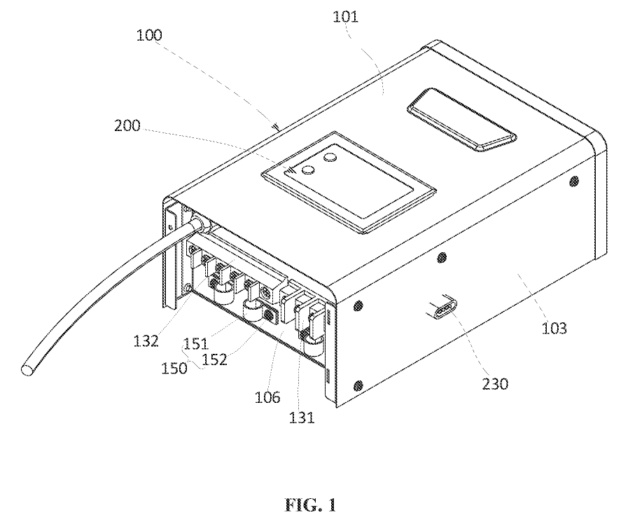

A multifunctional power supply provided in the present disclosure may be used in an outdoor environment, and is configured to convert a mains voltage (for example 110 V) into a voltage required for an electrical appliance including an eave lamp, a landscape lamp, and the like. As shown in FIGS. 1 to 3, the multifunctional power supply includes a housing 100 and a function panel 200. The function panel 200 is mounted on the housing 100. A transformer 110 and a circuit board 120 are disposed inside the housing 100, and the transformer 110 is electrically connected to the circuit board 120. The multifunctional power supply further includes an output end 130 that is connected to the housing 100 and is exposed outside the housing 100, and the output end 130 is electrically connected to the circuit board 120. The output end 130 is configured to externally connect to another electrical appliance, for example, the eave lamp and the landscape lamp to supply power to these electrical appliances. In some implementations, the multifunctional power supply may supply AC output. In some implementations, the multifunctional power supply may supply DC output. In some implementations, the multifunctional power supply may supply both AC output and DC output according to an actual requirement of the electrical appliance. An input cable may be further disposed on the housing 100. The input cable is configured to externally to an electric supply and supply power to the transformer 110 inside the housing 100. Therefore, the power is converted into a needed output voltage through the transformer 110 and a related circuit of the circuit board 120. The housing 100 may be made of an aluminum alloy material to provide enough rigid support and protect an electronic component therein. Therefore, in another implementation, the housing 100 may alternatively be made of a material like rubber.

The function panel 200 may be disposed on the housing 100 in a replaceable manner, and is electrically connected to the circuit board 120. The function panel 200 may be integrated with a physical button or a virtual button, or a nixie tube, or a display screen, or a wireless communication module, or the like, to provide a corresponding function. According to the multifunctional power supply provided in the present disclosure, the function panel 200 may be replaced according to a need, and therefore, a limitation that a common power supply should be carried to the site for checking and upgrading during maintenance and upgrade even if the common power supply has the functional panel 200, and an old function panel 200 originally mounted on the multifunctional power supply can be replaced with the maintained and upgraded function panel 200. The replaced function panel 200 can be freely carried to any place for maintenance and upgrade. For example, the replaced function panel 200 is updated to an intelligent module. The novel function panel 200 is matched with another component in the housing 100, and has a new light control mode, to quickly upgrade and modify a control mode of the landscape lamp connected to the multifunctional power supply.

For example, in some implementations, a user or maintenance personnel may upgrade and replace the function panel 200 without a wireless communication function as a function panel 200 with a wireless communication function. Such function panel 200 may be integrated with a controller as an intelligent module. The wireless communication function is not limited to WIFI communication, cellular communication, NFC communication or Bluetooth communication. After upgrade, the user can control output of the multifunctional power supply through a WIFI communication, or a cellular network, or an NFC signal or a Bluetooth signal, to expand functions and use scenarios. For example, in a scenario of a garden lamp or the eave lamp, these lamps are configured to normally illuminate. In an occasion including a party and the like, the user can send a switching instruction to the multifunctional power supply through mobile phone application (APP), remote control, or the like. A light-emitting mode of the lamp can be adjusted via the multifunctional power supply, to achieve effect of a horse race lamp, effect of a breathing lamp, and the like. Therefore, a lighting scene is enriched, and use convenience is improved.

The function panel 200 further can be matched with the circuit board 120, to provide more functions including a reliable overcurrent, over-voltage and over-temperature protection function, a corresponding light sensing function, for example, automatic detection for a brightness of environment light, and the like to the multifunctional power supply. Settings of a timer are combined, making the multifunctional power supply be automatically started to supply power to the electrical appliance at night.

The multifunctional power supply provided in the present disclosure has the function panel 200 that is disposed on the housing 100 in the replaceable manner. The function panel 200 can be directly switched to quickly achieve maintenance and system upgrade of the multifunctional power supply. Therefore, an illuminating brightness, a light color, a working mode, and the like of lamps including the landscape lamp, and the like are adjusted and upgraded more conveniently and quickly, to change and upgrade a light style.

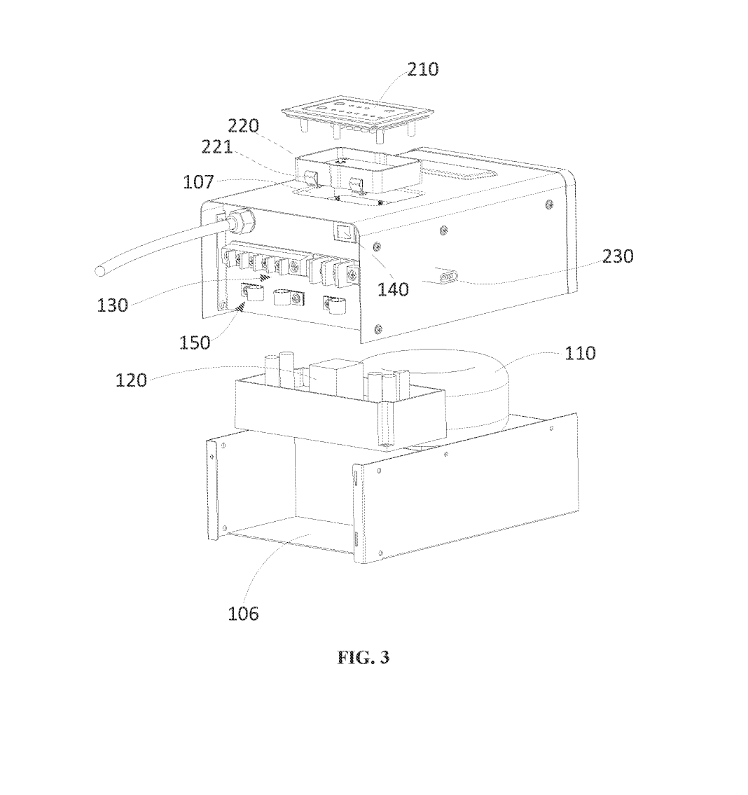

Optionally, in an embodiment of the present application, the circuit board120 includes an alternating current/direct current (AC/DC) conversion module, and the output end 130 includes at least one of a DC output end 131 and an AC output end 132. The AC/DC conversion module is a functional module for switching between an alternating current and a direct current by using a mature circuit technology. The multifunctional power supply provided in the present disclosure can provide two power supply modes of AC output and DC output, ensuing the multifunctional power supply to have comprehensive adaptation. Therefore, the multifunctional power supply is adaptive to more use usage scenarios, and decoration cost of a user is reduced in case of saving mounting space. In a specific implementation, as shown in FIG. 3, the housing 100 may be further provided with a selector switch 140, and the selector switch 140 is electrically connected to the circuit board 120, to switch output of the output end 130, and implement full DC output or full AC output. For example, the selector switch 140 has a first position and a second position. At the first position, the output end 130 is configured to output direct-current power. At the second position, the output end is configured to output AC power, meeting different power supply requirements of the electrical appliances.

Further, in some implementations, an output voltage is controlled via the function panel 200, and therefore, the output voltage is adjustable. For example, an adjustable range of an AC voltage is 10 V to 36 V, and an adjustable range of a direct-current voltage is 10 V to 36 V. In other words, the output voltage of the output end 130 can be flexibly adjusted via the function panel 200, to meet different power supply requirements of the electrical appliances.

In combination with the foregoing embodiment, in some specific implementations of an embodiment, as shown in FIGS. 1, 3, and 5, the DC output end 131 and the AC output end 132 are disposed on a same side of the housing 100 and are disposed in regions. In other words, without switching via the selector switch 140, the multifunctional power supply may have two voltage output modes, to adapt to more power supply scenarios. The two voltage output modes are set in regions, and the two output ends 130 are isolated from each other, preventing an operator from connecting a wire incorrectly, and improving wire connection convenience and safety. It should be noted that, the two voltage output modes are distinguished with different colors in regions, and voltage types can be further specified.

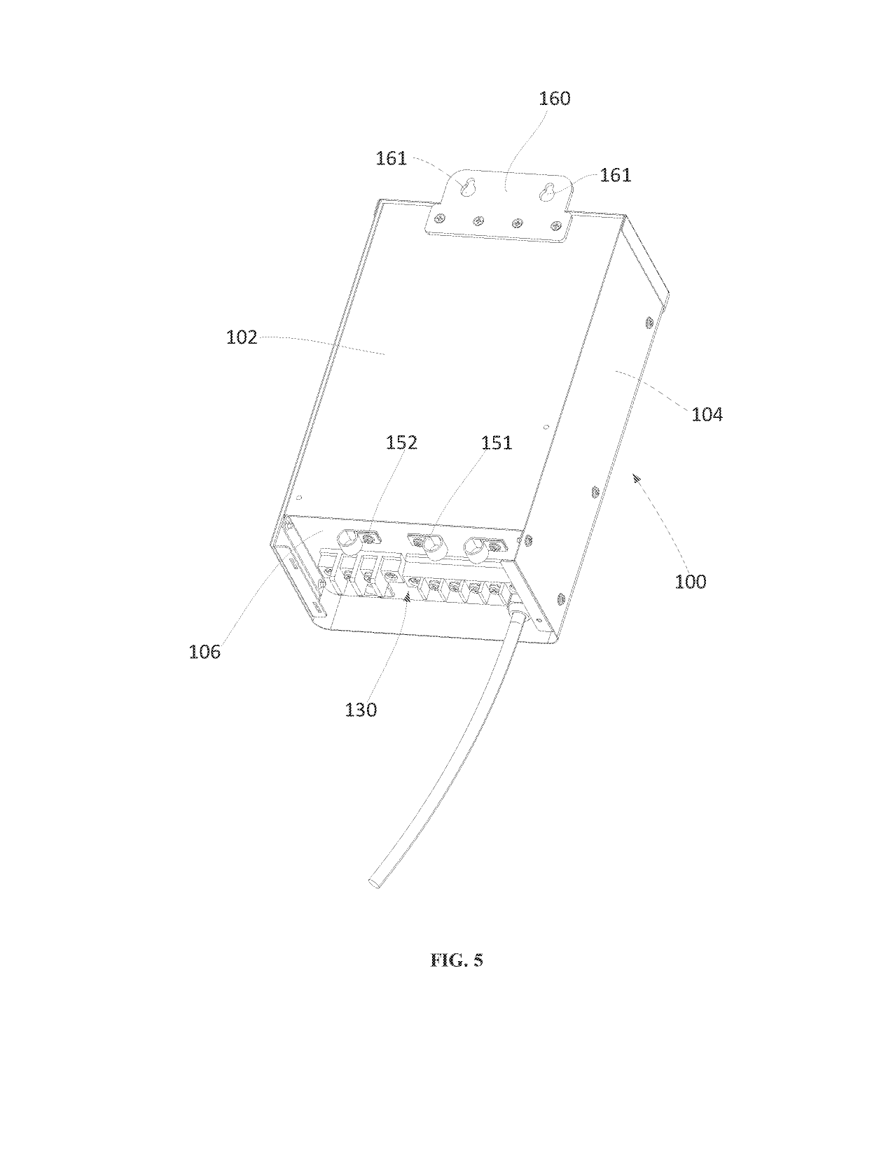

Optionally, in combination with the foregoing embodiment, in some implementations of an embodiment, as shown in FIGS. 1 and 5, the housing 100 is provided with a wire clamping part 150 on a side on which the output end 130 is located. The wire clamping part 150 includes an elastic clamp 151 and an adjusting bolt 152, and the adjusting bolt 152 is disposed at an opening of the elastic clamp 151 to adjust a size of the opening of the elastic clamp 151. The wire clamping part 150 is disposed to connect an external cable to the output end 130 more stably and neatly, improving use safety of the multifunctional power supply.

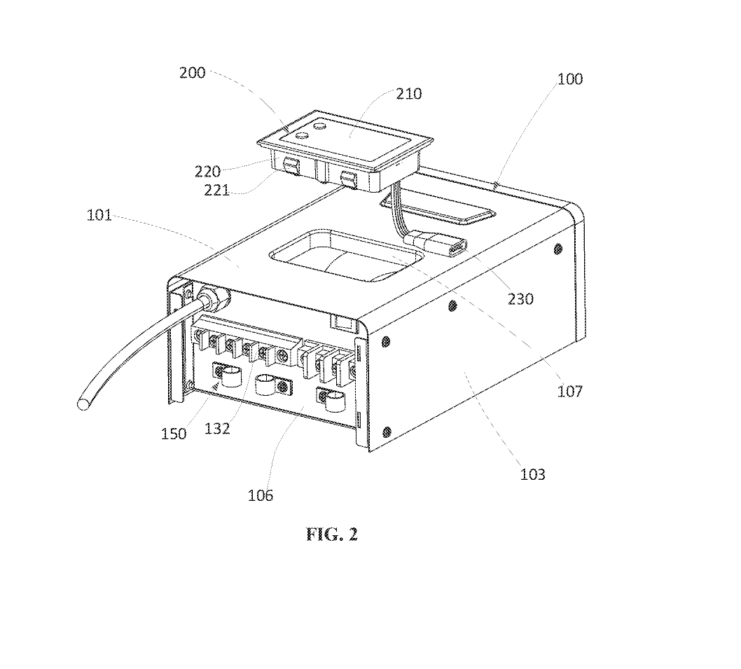

Specifically, in another embodiment of the present disclosure, as shown in FIGS. 2 and 3, the function panel 200 includes a control panel 210 and a connecting frame 220, the control panel 210 is disposed in the connecting frame 220, and the connecting frame 220 is detachably connected to the housing 100. There may be a plurality of detachable connecting manners between the connecting frame 220 and the housing 100. For example, the connecting frame 220 is mounted and fastened to a mounting opening of the housing 100 via a bolt. The control panel 210 is embedded in the connecting frame 220 or is fastened to the connecting frame 220 via a bolt. Certainly, the control panel 210 may alternatively be fixedly connected to the connecting frame 220 through clamping, bonding, or the like. The connecting frame 220 may alternatively be connected to the housing 100 detachably through clamping, or the like, to conveniently replace the function panel 200.

In combination with the foregoing embodiment, in a specific implementation, as shown in FIGS. 2 and 3, a plurality of elastic fasteners 221 are uniformly distributed on the connecting frame 220, and a mounting groove 107 is provided in the housing 100. The connecting frame 220 penetrates the mounting groove 107, and the elastic fastener 221 is clamped to an edge of the mounting groove 107. The connecting frame 220 is mounted in the mounting groove 107. The elastic fastener 221 on the connecting frame 220 elastically passes through the edge of the mounting groove 107, and naturally stretches in the housing 100, to limit and fasten the connecting frame 220. In this way, a threaded hole does not need to be provided on the housing 100, avoiding corrosion of related components, prolonging an outdoor service life of the multifunctional power supply, and ensuring replacement convenience of the control panel 210.

Optionally, in another embodiment of the present application, as shown in FIGS. 1 and 5, the housing 100 is approximately of a hollow rectangular box shape, and includes a first surface 101 and a second surface 102 that are disposed opposite to each other, and a peripheral surface connected between the first surface 101 and the second surface 102. The peripheral surface includes a first peripheral surface 103 and a second peripheral surface 104 that are disposed opposite to each other, and a third peripheral surface 105 and a fourth peripheral surface 106 that are connected between the first peripheral surface 103 and the second peripheral surface 104, and are disposed opposite to each other. The connecting frame 220 is detachably disposed on a side on which the first surface 101 is located, and the output end 130 is disposed on a side on which the fourth peripheral surface 106 is located. Generally, the first surface 101 is a front surface, the second surface 102 is a back surface, the third peripheral surface 105 is a top end surface, and the fourth peripheral surface 106 is a bottom end surface. The first peripheral surface 103 and the second peripheral surface 104 are separately located between the top end surface and the bottom end surface, and are two side surfaces of the housing 100. The function panel 200 is located on the first surface 101 for a convenient operation. The output end 130 is disposed on the fourth peripheral surface 106, namely, the bottom end surface, making a wiring operation convenient and avoiding intrusion error of rain.

With combination with the foregoing embodiment, in a specific implementation, as shown in FIGS. 2 and 3, the function panel 200 further includes a data connecting terminal 230, and the data connecting terminal 230 is detachably connected to a side on which the first peripheral surface 103 is located. The connecting terminal 230 is disposed on the first peripheral surface 103, making the operator conveniently import data into the multifunctional power supply at any time or export data in the multifunctional power supply. The data connecting terminal 230 is disposed on the first peripheral surface 103, preventing rain or dew from being accumulated in the data connecting terminal 230.

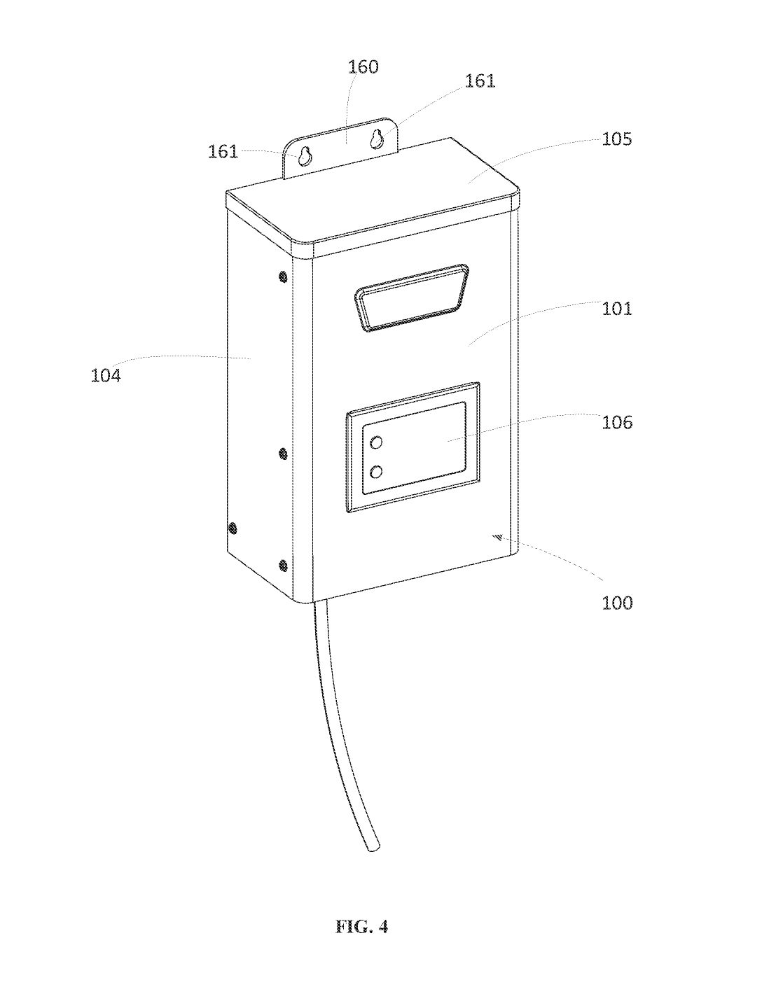

With combination with the foregoing embodiment, in another specific implementation, as shown in FIGS. 4 and 5, a connecting plate 160 is disposed on an edge that is on the second surface 102 and that is close to the third peripheral surface 105, and at least one connecting through hole 161 is provided on the connecting plate 160. The connecting plate 160 is disposed at a top end of a surface that is opposite to an end surface, on which the function panel 200 is located, of the housing 100, and at least one connecting through hole 161 is provided on the connecting plate 160. The function panel 200 is disposed on the first surface 101, namely, the front surface in an actual use scenario, directly facing the operator. A surface opposite to the end surface, on which the housing 100 is located, of the function panel 200 is the second surface 102, namely, the back surface, that generally leans against a wall, of the housing 100. The connecting plate 160 is disposed at a top end of the back surface. The connecting through hole 161 is provided on the connecting plate 160, and the housing 100 has a hanging point for convenient outdoor mounting. Generally, two connecting through holes 161 which are aligned in position are provided, ensuring that the multifunctional power supply is mounted stably outdoors, and is unlikely to shake.

The technical characteristics of the above embodiments can be employed in arbitrary combinations. To provide a concise description of these embodiments, all possible combinations of all the technical characteristics of the above embodiments may not be described; however, these combinations of the technical characteristics should be construed as falling within the scope defined by the specification as long as no contradiction occurs.

The above embodiments are merely illustrative of several implementations of the present disclosure, and the description thereof is specific and detailed. However, these embodiments may not be construed as a limitation to the patentable scope of the present disclosure. It should be pointed out that several variations and improvements may be made by those of ordinary skill in the art without departing from the conception of the present disclosure, but such variations and improvements should fall within the protection scope of the present disclosure. Therefore, the patent protection scope of the present disclosure should be subject to the appended claims.

What is claimed is:

1. A multifunctional power supply, comprising:
a housing, wherein a transformer and a circuit board are disposed inside the housing, and the transformer is electrically connected to the circuit board; an output end that is connected to the housing and is exposed outside the housing, wherein the output end is electrically connected to the circuit board; and
a function panel that is disposed on the housing in a replaceable manner, and is electrically connected to the circuit board.

2. The multifunctional power supply according to claim 1, wherein the circuit board comprises an alternating current/direct current (AC/DC) conversion module, and the output end comprises at least one of a DC output end and an AC output end.

3. The multifunctional power supply according to claim 2, wherein the DC output end and the AC output end are disposed on a same side of the housing and are disposed in regions.

4. The multifunctional power supply according to claim 2, wherein the housing is further provided with a selector switch, and the selector switch is electrically connected to the circuit board, to switch output of the output end, and implement full DC output or full AC output.

5. The multifunctional power supply according to claim 2, wherein the housing is provided with a wire clamping part on a side on which the output end is located, the wire clamping part comprises an elastic clamp and an adjusting bolt, and the adjusting bolt is disposed at an opening of the elastic clamp to adjust a size of the opening of the elastic clamp.

6. The multifunctional power supply according to claim 1, wherein the function panel comprises a control panel and a connecting frame, the control panel is disposed in the connecting frame, and the connecting frame is detachably connected to the housing.

7. The multifunctional power supply according to claim 6, wherein a plurality of elastic fasteners are uniformly distributed on the connecting frame, and a mounting groove is provided in the housing; and the connecting frame penetrates the mounting groove, and the elastic fastener is clamped to an edge of the mounting groove.

8. The multifunctional power supply according to claim 6, wherein the housing comprises a first surface and a second surface that are disposed opposite to each other, and a peripheral surface connected between the first surface and the second surface; the peripheral surface comprises a first peripheral surface and a second peripheral surface that are disposed opposite to each other, and a third peripheral surface and a fourth peripheral surface that are connected between the first peripheral surface and the second peripheral surface, and are disposed opposite to each other; and the connecting frame is detachably disposed on a side on which the first surface is located, and the output end is disposed on a side on which the fourth peripheral surface is located.

9. The multifunctional power supply according to claim 8, wherein the function panel further comprises a data connecting terminal, and the data connecting terminal is detachably connected to a side on which the first peripheral surface is located.

10. The multifunctional power supply according to claim 8, wherein a connecting plate is disposed on an edge that is on the second surface and that is close to the third peripheral surface, and at least one connecting through hole is provided on the connecting plate.
